(19) United States
(12) Patent Application Publication
(10) Pub. No.: US 2012/0152325 A1
(43) Pub. Date: Jun. 21, 2012

(54) JUNCTION BOX ATTACHMENT TO SOLAR MODULE LAMINATE

(75) Inventors: Michael L. Podkin, Tucson, AZ (US); Darren Verebelyi, Tucson, AZ (US)

(73) Assignee: Global Solar Energy, Inc., Tucson, AZ (US)

(21) Appl. No.: 13/165,114

(22) Filed: Jun. 21, 2011

Related U.S. Application Data
(60) Provisional application No. 61/357,025, filed on Jun. 21, 2010.

(51) Int. Cl. H01L 31/048; H01L 31/18

(52) U.S. Cl. 136/251; 438/66; 257/E31.117

(57) ABSTRACT

A multi-layer photovoltaic module including an integrated junction box base plate. A portion of the top layer of the module may be removed to form an aperture, within which the base plate may be disposed. Terminal connections of a string of photovoltaic cells may be exposed within the aperture, so that a base plate having an access opening allows electrical connections with the string when placed within the aperture. The base plate may be placed within the encapsulating layer aperture prior to lamination of the module layers, so that the base plate becomes more securely integrated into the module during the lamination process.

### CROSS-REFERENCE TO RELATED APPLICATIONS

This application claims priority from U.S. Provisional Patent Application Ser. No. 61/357,025 filed Jun. 21, 2010 which is incorporated herein by reference. Also incorporated by reference in their entireties are the following patent applications: Ser. No. 12/364,440 filed Feb. 2, 2009, Ser. No. 12/587,111 filed Sep. 30, 2009, Ser. No. 12/980,151 filed Dec. 28, 2010 and Ser. No. 12/980,201 filed Dec. 28, 2010.

### BACKGROUND

The field of photovoltaics generally relates to multi-layer materials that convert sunlight directly into DC electrical power. The basic mechanism for this conversion is the photovoltaic effect, first observed by Antoine-César Becquerel in 1839, and first correctly described by Einstein in a seminal 1905 scientific paper for which he was awarded a Nobel Prize for physics. In the United States, photovoltaic (PV) devices are popularly known as solar cells or PV cells. Solar cells are typically configured as a cooperating sandwich of p-type and n-type semiconductors, in which the n-type semiconductor material (on one “side” of the sandwich) exhibits an excess of electrons, and the p-type semiconductor material (on the other “side” of the sandwich) exhibits an excess of holes, each of which signifies the absence of an electron. Near the p-n junction between the two materials, valence electrons from the n-type layer move into neighboring holes in the p-type layer, creating a small electrical imbalance inside the solar cell. This results in an electric field in the vicinity of the metallurgical junction that forms the electronic p-n junction.

When an incident photon excites an electron in the cell into the conduction band, the excited electron becomes unbound from the atoms of the semiconductor, creating a free electron/hole pair. Because, as described above, the p-n junction creates an electric field in the vicinity of the junction, electron/hole pairs created in this manner near the junction tend to separate and move away from junction, with the electron moving toward the electrode on the n-type side, and the hole moving toward the electrode on the p-type side of the junction. This creates an overall charge imbalance in the cell, so that if an external conductive path is provided between the two sides of the cell, electrons will move from the n-type side back to the p-type side along the external path, creating an electric current. In practice, electrons may be collected from at or near the surface of the n-type side by a conducting grid that covers a portion of the surface, while still allowing sufficient access into the cell by incident photons.

Such a photovoltaic structure, when appropriately located electrical contacts are included and the cell (or a series of cells) is incorporated into a closed electrical circuit, forms a working PV device. As a standalone device, a single conventional solar cell is not sufficient to power most applications. As a result, solar cells are commonly arranged into PV modules, or “strings,” by connecting the front of one cell to the back of another, thereby adding the voltages of the individual cells together in electrical series. Typically, a significant number of cells are connected in series to achieve a usable voltage. The resulting DC current then may be fed through an inverter, where it is transformed into AC current at an appropriate frequency, which is chosen to match the frequency of AC current supplied by a conventional power grid. In the United States, this frequency is 60 Hertz (Hz), and most other countries provide AC power at either 50 Hz or 60 Hz.

One particular type of solar cell that has been developed for commercial use is a “thin-film” PV cell. In comparison to other types of PV cells, such as crystalline silicon PV cells, thin-film PV cells require less light-absorbing semiconductor material to create a working cell, and thus can reduce processing costs. Thin-film based PV cells also offer reduced cost by employing previously developed deposition techniques for the electrode layers, where similar materials are widely used in the thin-film industries for protective, decorative, and functional coatings. Common examples of low cost commercial thin-film products include water impermeable coatings on polymer-based food packaging, decorative coatings on architectural glass, low emissivity thermal control coatings on residential and commercial glass, and scratch and anti-reflective coatings on eyewear. Adopting or modifying techniques that have been developed in these other fields has allowed a reduction in development costs for PV cell thin-film deposition techniques.

Furthermore, thin-film cells have exhibited efficiencies approaching 20%, which rivals or exceeds the efficiencies of the most efficient crystalline cells. In particular, the semiconductor material copper indium gallium diselenide (CIGS) is stable, has low toxicity, and is truly a thin film, requiring a thickness of less than two microns in a working PV cell. As a result, to date CIGS appears to have demonstrated the greatest potential for high performance, low cost thin-film PV products, and thus for penetrating bulk power generation markets. Other semiconductor variants for thin-film PV technology include copper indium diselenide, copper indium disulfide, copper indium aluminum diselenide, and cadmium telluride.

Some thin-film PV materials may be deposited either on rigid glass substrates, or on flexible substrates. Glass substrates are relatively inexpensive, generally have a coefficient of thermal expansion that is a relatively close match with the CIGS or other absorber layers, and allow for the use of vacuum deposition systems. However, when comparing technology options applicable during the deposition process, rigid substrates suffer from various shortcomings during processing, such as a need for substantial floor space for processing equipment and material storage, expensive and specialized equipment for heating glass uniformly to elevated temperatures at or near the glass annealing temperature, a high potential for substrate fracture with resultant yield loss, and higher heat capacity with resultant higher electricity cost for heating the glass. Furthermore, rigid substrates require increased shipping costs due to the weight and fragile nature of the glass. As a result, the use of glass substrates for the deposition of thin films may not be the best choice for low-cost, large-volume, high-yield, commercial manufacturing of multi-layer functional thin-film materials such as photovoltaics.

In contrast, roll-to-roll processing of thin flexible substrates allows for the use of compact, less expensive vacuum systems, and of non-specialized equipment that already has been developed for other thin film industries. PV cells based on thin flexible substrate materials such as thin sheets of stainless steel also exhibit a relatively high tolerance to rapid heating and cooling and to large thermal gradients (resulting in a low likelihood of fracture or failure during processing), require comparatively low shipping costs, and exhibit a greater ease of installation than cells based on rigid substrates. Additional details relating to the composition and manufacture of thin film PV cells of a type suitable for use with the presently disclosed teachings may be found, for example, in U.S. Pat. Nos. 6,310,281, 6,372,538, and 7,194,197, all to Wendt et al. These patents are hereby incorporated into the present disclosure by reference for all purposes.

As noted previously, a significant number of PV cells often are connected in series to achieve a usable voltage, and thus a desired power output. Such a string of PV cells can be formed, for example, using conductive tabs or ribbons, where a given tab electrically connects one polarity of a first cell to the opposite polarity of an adjacent cell. Alternatively, cells may be interconnected to form strings by monolithic integration techniques, i.e., by creating the electrical connections between cells in situ on the continuous substrate. Further details about forming modules of photovoltaic cells can be found in U.S. Patent Application Publication No. 2009-0255565-A1 (corresponding to application Ser. No. 12/364,440 filed Feb. 2, 2009), which is hereby incorporated by reference into the present disclosure.

### SUMMARY

To protect a flexible module of interconnected PV cells from environmental elements while retaining its flexibility, the module may be laminated between a flexible, transparent, protective top layer or “frontsheet” and a flexible, protective bottom layer or “backsheet.” A junction box then may be incorporated into the module to terminate its internal electrical connections and to extend electrical leads out of the module in a usable and well protected form. Integrating the junction box with a flexible module can be challenging when the frontsheet of the module has a non-stick top surface configured to shed water and dirt, as is often the case. Although known sealants and adhesives can be used to attach a junction box to such a surface, the resulting seal can fail during installation or under prolonged exposure to environmental elements. Accordingly, it may be desirable to attach a junction box to a flexible solar module in an improved manner that increases the likelihood of a secure connection between the junction box and the module.

The present teachings disclose thin film photovoltaic modules that include a junction box integrated into either the top laminate (frontsheet) or the bottom laminate (backsheet) of the module. According to the present teachings, the base plate of a junction box may be integrated with the module during lamination.

### BRIEF DESCRIPTION OF THE DRAWINGS

FIG. 1 is a schematic plan view depicting portions of an illustrative photovoltaic (PV) module.

FIG. 2 is a partially exploded isometric view of a portion of an illustrative PV module showing various layers.

FIG. 3 is a partially cut away top view of a portion of a PV module including an integrated junction box according to aspects of the present teachings, showing a flanged base plate on the left side and a non-flanged base plate on the right side.

FIG. 4 is a schematic exploded side view of the PV module of FIG. 3, showing further details of the integration of an illustrative junction box with other portions of a module, and depicting a flanged base plate on the left side and a non-flanged base plate on the right side.

FIG. 5 is a block diagram depicting an illustrative method of manufacturing a PV module according to aspects of the present teachings.

### DETAILED DESCRIPTION

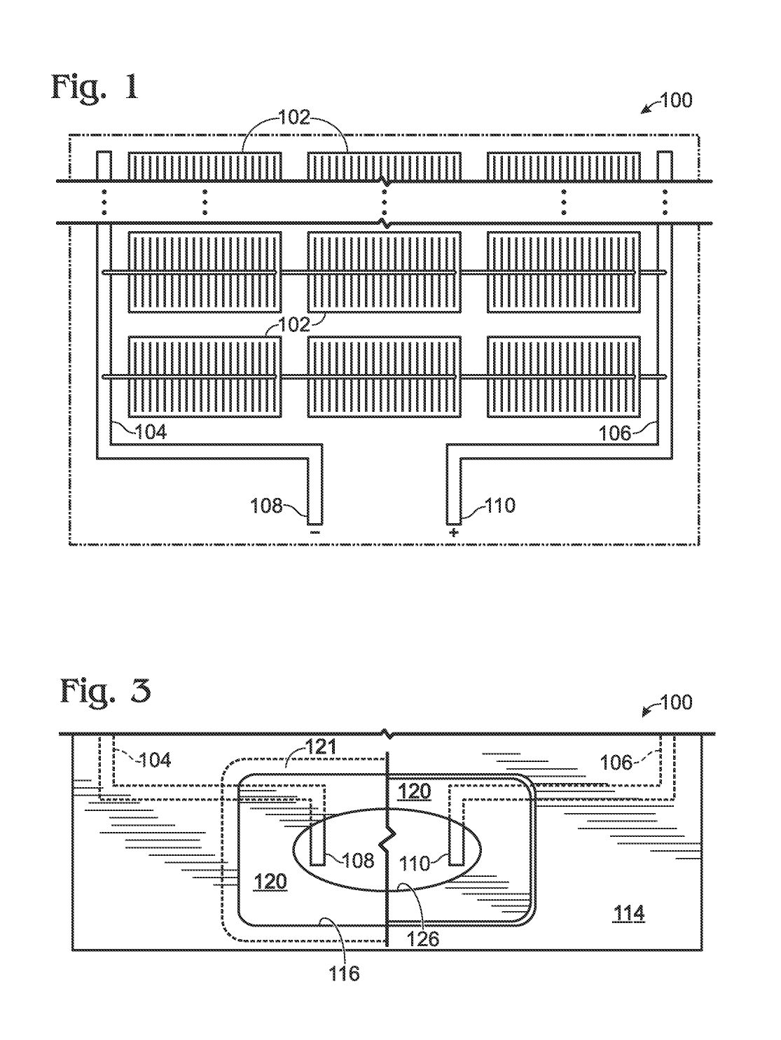

FIG. 1 is a schematic plan view depicting portions of an illustrative photovoltaic (PV) module, generally indicated at 100, according to aspects of the present teachings. Module 100 includes a string of electrically connected PV cells 102, which in the example of FIG. 1 includes two or more series-connected groups of three cells, with the groups connected in parallel. In general, any number of PV cells may be interconnected in series and/or parallel to produce a desired voltage for a particular application.

Cells 102 each may include a flexible substrate upon which successive layers are disposed, such as a bottom electrode layer, an active photovoltaic layer, a top electrode layer, and a collection grid. In some cases, the active photovoltaic layer may include cadmium, indium, gallium and selenium, i.e., cells 102 may be thin film, CIGS-type cells. However, the present teachings are not restricted to any particular type of PV cell.

A pair of bus ribbons 104, 106 extends from interconnected cells 102 to form electrically conductive terminal ends 108, 110. Terminal ends 108, 110 extend from the string and are configured to carry opposite electrical polarities corresponding to a voltage generated by the string. The use of bus ribbons is merely illustrative. More generally, the voltage generated by PV modules according to the present teachings may be carried by any appropriate conductive elements, such as ribbons, wires, bars, or similar structures chosen to have properties suitable for a particular application.

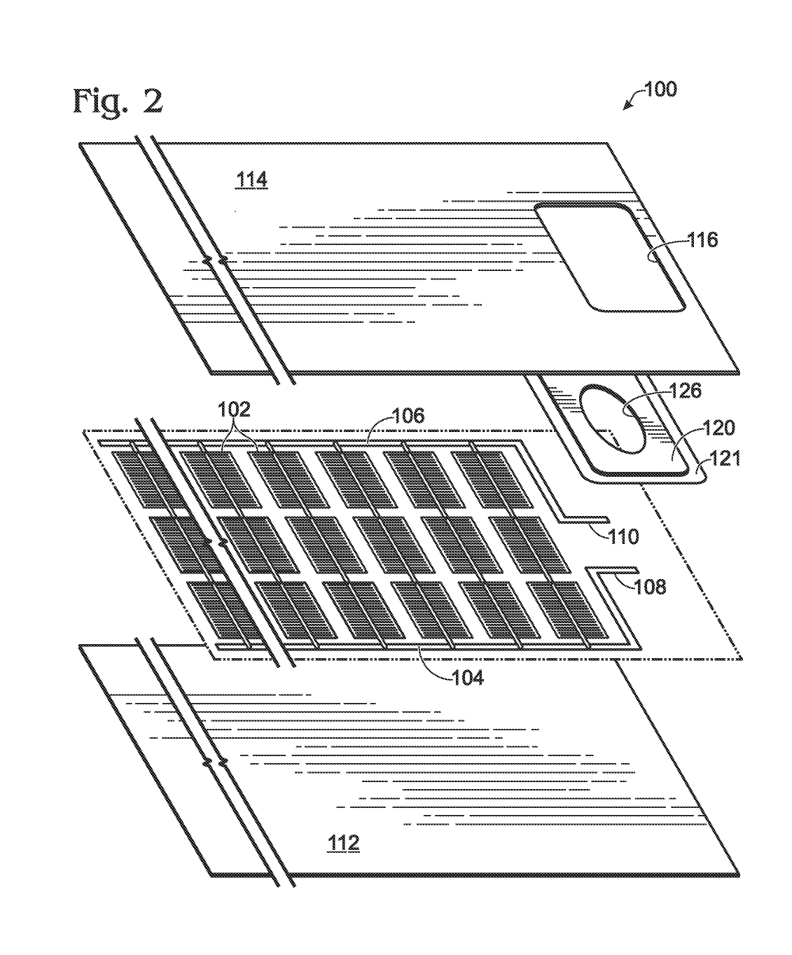

FIG. 2 is a partially exploded isometric view of a portion of module 100, showing that cells 102 are generally disposed between a substrate or protective backsheet 112 and a superstrate or protective frontsheet 114. Backsheet 112 may be a multi-layer backsheet and may include a vapor barrier. For example, backsheet 112 may include a protective bottom layer formed of a material such as the polyvinyl fluoride material Tedlar® manufactured by the DuPont Corporation, a vapor barrier layer, and/or a protective top layer formed of a material such as polyethylene terephthalate (PET). Suitable vapor barriers may include thin sheets of aluminum, copper, or stainless steel, among others. Adhesives may be used to join the vapor barrier layer to the protective bottom and top layers.

Frontsheet 114 will typically be formed from a partially transparent flexible polymer that acts to protect the underlying photovoltaic cells from environmental elements while still allowing substantial transmission of solar radiation at desired wavelengths. For example, various fluoropolymers applied either as flexible films or as liquids may be well suited as materials for protective transparent frontsheet 114. However, the present teachings are not limited to any particular choice of frontsheet material, and may also be implemented with frontsheets that include glass or other rigid transparent materials.

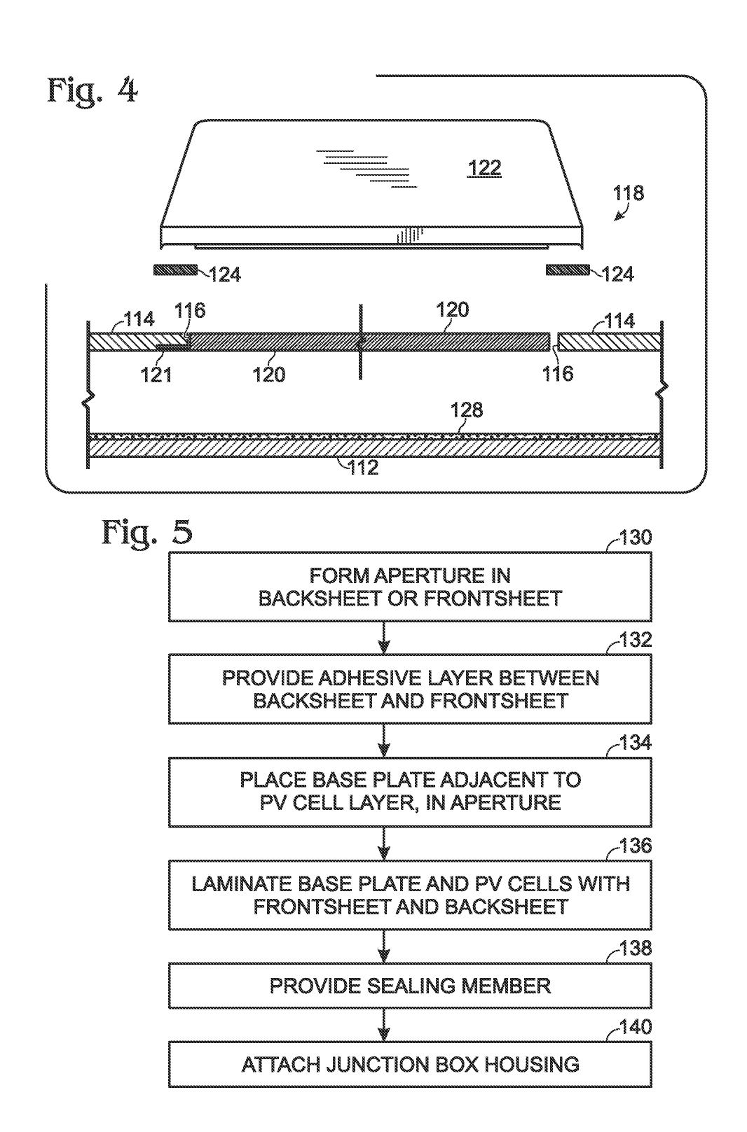

As shown in FIG. 2 and also as depicted in FIG. 3, which is a magnified top view of a portion of module 100, a cutout or aperture 116 may be formed in frontsheet 114. More generally, an aperture such as aperture 116 may be formed in a selected one of frontsheet 114 or backsheet 112, but the aperture is shown formed in frontsheet 114 in the depicted embodiment. Regardless of whether aperture 116 is formed in frontsheet 114 or backsheet 112, it may be disposed in a location to overlap terminal ends 108 and 110. Furthermore, aperture 116 may be configured so that a junction box, generally indicated at 118, may be disposed at least partially within the aperture. Junction box 118 may be any suitable structure configured to contain and protect electrical connections, including those of terminal ends 108, 110. For example, junction box 118 may include a base plate 120, a housing 122, and/or a sealing element 124, as shown in the illustrative junction box 118 of FIG. 4.

More specifically, in some examples such as the one shown in FIG. 3, base plate 120 of junction box 118 may be disposed substantially within aperture 116. Base plate 120 may be configured to overlap terminal ends 108, 110 within the aperture. Furthermore, base plate 120 may include an access opening 126 to allow terminal ends 108, 110 to pass through base plate 120 into an interior portion of junction box 118. Alternatively, access opening 126 may allow portions of junction box 118 or other structures such as external leads, connectors, or cables (not shown) to pass through base plate 120 to electrically connect to terminal ends 108, 110.

FIG. 4 shows a partially exploded side view of an illustrative module 100, illustrating further details of construction. Backsheet 112 may be disposed at the bottom of module 100, to protect module 100 from moisture and contamination from below. PV cells 102 may be disposed above backsheet 112, and are typically attached to backsheet 112 by an adhesive. For example, an adhesive encapsulant layer 128 may be disposed above backsheet 112. In some cases, the bottom and/or top surfaces of cells 102 also may be coated with separate adhesive encapsulant layers (not shown). These adhesive layers, including adhesive encapsulant layer 128 and any other adhesives applied to cells 102, may be configured to securely attach frontsheet 114 and base plate 120 to backsheet 112.

Adhesive encapsulant layers may be formed of materials such as ethylene vinyl acetate (EVA) polyvinyl butyral (PVB), ethylene copolymers, various ionomers, thermoplastic urethanes, silicones, polychlortrifluorethylene, fluorothermoplastics, and polyolefin copolymers. Generally, adhesive layers disposed above cells 102 may be constructed from materials largely transparent to solar radiation, whereas adhesive layers disposed below cells 102 need not be constructed from transparent materials.

As FIG. 4 indicates, base plate 120 of junction box 118 may be embedded within module 100 by disposing base plate 120 within aperture 116 of frontsheet 114. Typically, base plate 120 may be placed on top of adhesive encapsulant layer 128, and may reside in the finished module 100 at approximately the same level within module 100 as cells 102. As indicated in FIG. 3, base plate 120 may be disposed above terminal ends 108, 110. Thus, from bottom to top, a typical arrangement of components of module 100 surrounding but not including base plate 120 may be as follows: backsheet 112; bottom adhesive encapsulant layer 128; PV cells 102 and bus ribbons 104, 106; top adhesive layer (not shown); frontsheet 114. In the regions where the base plate is disposed, this bottom to top arrangement may instead be: backsheet 112; bottom adhesive encapsulant layer 128; bus ribbons 104, 106 (under at least a portion of the base plate); base plate 120.

Aperture 116 may typically be formed in frontsheet 114 and in any top adhesive layer that may be applied to frontsheet 114 prior to lamination of the module components. Backsheet 112 and frontsheet 114 thus may be configured to be laminated together so as to enclose and protect a string of cells 102 while providing access to base plate 120 through aperture 116. Furthermore, although base plate 120 is typically placed into position on bottom adhesive encapsulant layer 128 prior to lamination, the lamination process may serve to more securely bond base plate 120 to the underlying adhesive layer, and may join base plate 120 to the surrounding laminate and/or surrounding adhesive of frontsheet 114.

For example, base plate 120 may be sized larger than aperture 116 such that a peripheral portion of base plate 120 may be sandwiched between frontsheet 114 and lower layers of module 100 while still providing access to access opening 126.

The overall size of base plate 120 relative to aperture 116 may be selected to allow more or less overlap of frontsheet 114, with a corresponding effect on water preclusion and structural strength. In some examples, the overall size of base plate 120 may be enlarged by including a tapered or flanged portion 121 around a periphery of base plate 120 such as that shown on the left side of FIGS. 3 and 4.

After frontsheet 114 and base plate 120 are bonded to underlying portions of module 100, junction box housing 122 may be attached to base plate 120, to protect base plate 120 and any internal wiring or electrical connections from exposure to the elements and/or to provide an electrical interface between junction box 118 and a nearby power grid. The electrical interface may be configured to provide power generated by module 100 to a power grid either directly as DC power, or through an intermediate power inverter as AC power.

Junction box housing 122 may be a single piece, such as a simple cover, or may include multiple portions fitted or attached together. Housing 122 may be configured to provide an external electrical interface, and may also include portions such as terminals or sockets configured to allow electrical connections within junction box 118. For example, housing 122 may include portions configured to allow termination of bus ribbons 104, 106 within junction box 118 such as by soldering or using plug-in leads. In other examples, instead of terminal ends 108, 110 of bus ribbons 104, 106 being brought into junction box 118, housing 122 may include portions which protrude through access opening 126 and make electrical contact with bus ribbons 104 and 106.

Junction box housing 122 may be attached to base plate 120 by any suitable method, such as by use of welding, adhesive, and/or fasteners. To provide a waterproof seal between junction box housing 122 and base plate 120 and/or frontsheet 114, a sealing element 124 such as a gasket or a layer of sealant may be included as shown in FIG. 4. Sealing element 124 may be disposed around a periphery of aperture 116, between frontsheet 114 and junction box housing 122. Sealing element 124 also may be configured to overlap the interface between base plate 120 and the surrounding laminate, to further improve the integrity of that interface. In the example shown in FIG. 4, base plate 120 is sized smaller than aperture 116. As discussed in other examples above, base plate 120 may be sized larger than aperture 116. In either case, an overlapping sealing element 124 may be used to improve integrity and preclude moisture from entering the module.

To transfer power from the junction box to the power grid or inverter, cables or wires (not shown) may be attached to, passed through, or integrated with junction box 118. In some examples, an internal portion of junction box 118, such as a terminal block, connector posts, or a socket arrangement (not shown), may make electrical contact with terminal ends 108, 110. Outgoing power cables may be attached to and extend directly from the internal portion of junction box 118, such that outgoing power cables are in electrical communication with bus ribbons 104, 106. Attachment of wires and cables may be by any suitable method, such as by crimping, soldering, or clipping.

According to the present teachings, the arrangement of junction box 118 described above may be inverted, so that junction box 118 may be attached to the bottom of PV module 100 rather than the top. In that case, junction box 118 would be adhesively attached to the bottom of frontsheet 114 while making contact with terminal ends 108, 110 of bus ribbons 104, 106, and would fit through an aperture 116 in backsheet 112 and bottom adhesive layer(s) in the same fashion as that described above. An arrangement of this type may result in a smaller impact on the solar module, because the junction box would not utilize any exposed surface area.

FIG. 5 shows an illustrative method for constructing a PV module 100 according to aspects of the present teaching. This illustrative method may include some or all of the steps shown, including steps 130, 132, 134, 136, 138, and/or 140, and steps may not necessarily need to be performed in the order shown.

Step 130 may include forming an opening such as aperture 116 in a selected one of backsheet 112 or frontsheet 114 and in any associated adhesive layers. Aperture 116 may be any opening configured to allow at least a portion of base plate 120 to be disposed within the opening. As described above, relative sizing of aperture 116 with respect to base plate 120 may be selected based on desired moisture preclusion and structural integrity characteristics, as well as other considerations.

Step 132 may include providing at least one adhesive encapsulant layer between backsheet 112 and frontsheet 114. As described above, adhesive layers may secure other layers to base plate 120 in a lamination process.

Step 134 may include placing or disposing a base plate 120 at least partially in the aperture 116 formed in step 130. Regardless of whether aperture 116 is formed in frontsheet 114 or backsheet 112, base plate 120 may be disposed in substantially the same layer as an interconnected string of PV cells 102. The string of PV cells 102 may be electrically connected via bus ribbons 104, 106, terminating in terminal ends 108, 110 as described above. Furthermore, base plate 120 may be placed or disposed such that a bottom surface of base plate 120 overlies bus ribbons 104, 106 and terminal ends 108, 110. An access opening 126 may be provided in base plate 120 to provide access to terminal ends 108, 110 of the string of interconnected PV cells 102.

Step 136 may include laminating base plate 120 and the string of electrically connected PV cells 102 with backsheet 112 and frontsheet 114 and any associated adhesive layers such as adhesive encapsulant layer 128. This lamination step may include forming a substantially waterproof perimeter around the base plate. Furthermore, the waterproof perimeter may be improved by causing a portion of the selected one of backsheet 112 or frontsheet 114 to overlap base plate 120, in conjunction with a portion of a layer of adhesive encapsulant.

Step 138 may include placing or disposing a sealing member such as sealing element 124, which may include a gasket or sealant layer, between housing 122 of step 140 and the selected one of backsheet 112 or frontsheet 114. The sealing member may be configured to prevent moisture from penetrating the interface between base plate 120 and the selected one of backsheet 112 or frontsheet 114. The sealing member may also be disposed to overlap the interface between aperture 116 and base plate 120, such that integrity of that interface is improved.

Step 140 may include providing and attaching a junction box housing 122, such that housing 122 is attached to base plate 120 by any suitable method. As described above, attachment may be accomplished by methods such as ultrasonic welding, using fasteners such as clips, by mechanical latching, and/or by using adhesives. If a sealing member is positioned in step 138, housing 122 would be attached over the sealing member. Housing 122 may be any suitable substantially waterproof housing or cover, and may be formed as a single piece or may include more than one portion fitted or attached together.

The disclosure set forth above may encompass multiple distinct inventions with independent utility. Although each of these inventions has been disclosed in its preferred form(s), the specific embodiments thereof as disclosed and illustrated herein are not to be considered in a limiting sense, because numerous variations are possible. The subject matter of the present teachings includes all novel and nonobvious combinations and subcombinations of the various elements, features, functions, and/or properties disclosed herein.

We claim:

1. A photovoltaic module, comprising:
a protective backsheet;
a string of electrically connected photovoltaic cells disposed above the backsheet;
a partially transparent protective frontsheet disposed above the string; and
a junction box configured to receive electrical power from the string and disposed at least partially within an aperture formed in a selected one of the frontsheet or the backsheet.

2. The module of claim 1, wherein a base plate of the junction box is disposed substantially within the aperture, and wherein the base plate overlaps electrically conductive terminal ends of the string.

3. The module of claim 2, wherein the base plate provides access to the terminal ends through an opening in the base plate.

4. The module of claim 2, further comprising a junction box housing disposed adjacent to the base plate and configured to protect the base plate and the terminal ends from environmental elements.

5. The module of claim 4, further comprising a sealing element disposed between the housing and the selected one of the frontsheet or the backsheet.

6. The module of claim 2, wherein the base plate is configured to bond with the selected one of the frontsheet or the backsheet during a lamination process, to form a substantially waterproof perimeter around the base plate.

7. A photovoltaic module, comprising:
a string of electrically connected photovoltaic cells disposed between a protective backsheet and a protective frontsheet;
a pair of electrically conductive terminal ends extending from the string and configured to carry opposite electrical polarities corresponding to a voltage generated by the string; and
a junction box base plate, disposed at least partially within an aperture formed in a selected one of the frontsheet or the backsheet and configured to overlap the terminal ends.

8. The module of claim 7, wherein the base plate is embedded within the module by lamination.

9. The module of claim 7, wherein the terminal ends are accessible through an opening formed in the base plate.

10. The module of claim 7, further comprising a junction box housing configured to fit over the base plate and to inhibit moisture from entering the aperture formed in the selected one of the frontsheet or the backsheet.

11. The module of claim 10, wherein the junction box housing is configured to provide an external electrical interface.

12. The module of claim 11, wherein a portion of the junction box housing is configured to make electrical contact with the terminal ends.

13. The module of claim 10, further comprising a sealing gasket disposed between the junction box base plate and the junction box housing.

14. A method of manufacturing a photovoltaic module, comprising:
forming an aperture in a selected one of a protective backsheet or a light-transmitting protective frontsheet;
disposing a junction box base plate at least partially within the aperture; and
laminating the base plate and an interconnected string of photovoltaic cells between the frontsheet and the backsheet.

15. The method of claim 14, wherein the step of laminating forms a substantially waterproof perimeter around the base plate.

16. The method of claim 14, further comprising attaching a substantially waterproof housing to the base plate.

17. The method of claim 16, further comprising disposing a sealing member between the housing and the selected one of the backsheet or the frontsheet, wherein the sealing member is configured to prevent moisture from penetrating the interface between the base plate and the selected one of the backsheet or the frontsheet.

18. The method of claim 14, further comprising providing an opening in the base plate configured to provide access to terminal ends of the string.

19. The method of claim 14, further comprising providing at least one layer of adhesive encapsulant between the backsheet and the frontsheet.

20. The method of claim 19, wherein the step of laminating causes a portion of the selected one of the backsheet or the frontsheet to overlap the base plate, in conjunction with a portion of the layer of adhesive encapsulant, to form a substantially waterproof perimeter around the base plate.
